(19) United States
(12) Patent Application Publication
(10) Pub. No.: US 2025/0003052 A1
(43) Pub. Date: Jan. 2, 2025

(54) COATING SOURCE, COATING INSTALLATION AND METHOD FOR COATING SUBSTRATES

(71) Applicant: SINGULUS TECHNOLOGIES AG, Kahl am Main (DE)

(72) Inventors: Andreas LUDWIG, Aschaffenburg (DE); Sergiy BORODIN, Aschaffenburg (DE)

(21) Appl. No.: 18/711,083

(22) PCT Filed: Oct. 7, 2022
(86) PCT No.: PCT/EP2022/077896

§ 371 Date: May 16, 2024

(30) Foreign Application Priority Data
Dec. 17, 2021 (DE) 10 2021 006 249.3

(51) Int. Cl. C23C 14/24

(52) U.S. Cl. CPC C23C 14/243

(57) ABSTRACT

The present invention relates to a coating source for a coating plant, a coating plant with such a coating source and a method for coating substrates using such a coating source.

The present invention relates to a coating source for a coating plant, a coating plant comprising such a coating source and a method for coating substrates using such a coating source.

When coating large-scale glass substrates or a plurality of Si wafers on a large-scale carrier using physical or chemical vapor deposition, for example, coating sources with a crucible are typically used, in which the material to be vaporized is heated to such an extent that it vaporizes and is available for coating. Such coating sources are known, for example, from U.S. Pat. No. 6,559,065 B2, JP 2012-216373 A, DE 24 30 653 A1 and U.S. Pat. No. 3,984,585. However, with such coating sources, the problem always arises that evaporation material can be deposited at different parts of the crucible and in particular in the region of the outlet opening, which can thus impair the quality of the coating or, in the case of top-down evaporation sources, can also lead to material adhering in the region of the outlet opening falling down onto the substrate surface. Further coating sources are disclosed in DE 100 21 530 C1, DE 44 22 697 C1 and WO 2014/168352 A1.

It is thus an object of the present invention to provide a coating source, a coating plant and a coating method by means of which this problem is overcome. This problem is solved by the subject matter of the independent claims. Preferred features of the subject-matter according to the invention are described in the dependent claims.

Accordingly, the present invention is directed to a coating source for a coating plant, wherein the coating source comprises a crucible for vaporizing coating material and at least one outlet opening for vaporized coating material. The coating source comprises a first heating source for heating the crucible and/or the coating material and a second heating source for heating the at least one outlet opening.

In other words, the present invention is based inter alia on the idea of providing two independent heating sources in order to be able to control the temperature of the crucible and/or the coating material, on the one hand, and the temperature of the outlet opening, on the other hand, independently of each other. In doing so, it can be ensured, for example, that the outlet opening is heated during the coating process to such an extent that a deposit of coating material in the region of the outlet opening can be effectively prevented. Alternatively or additionally, the second heating source for heating the at least one outlet opening can also be used to clean the outlet opening, for example following a coating process, by heating it significantly.

The first heating source can, for example, comprise one or more heating elements integrated into the crucible walls and/or one or more first infrared (IR) radiation sources. The second heating source is preferably one or more second IR radiation sources.

Preferably, the crucible is closed with a lid. The first and/or second IR radiation sources are preferably arranged outside said closed crucible, wherein the lid is at least semi-transparent for the IR radiation of the first and/or second IR radiation sources. Preferably, the lid has a mean transmission of at least 5%, more preferably at least 10% and particularly preferably at least 20% over the wavelength range from 0.5 μm to 5.0 μm. This is to ensure that, on the one hand, sufficient radiant energy from the IR radiation sources passes through the lid to the coating material or the outlet opening and, on the other hand, sufficient radiant energy is absorbed by the lid so that its inside is hot enough to prevent coating material from being deposited.

Preferably, the at least one outlet opening is arranged on a first, preferably lower, side of the crucible and the lid closes a second, opposite side of the crucible. The lower side of the crucible refers to the side of the crucible that faces downwards when the coating source is in use during a coating process. One or more closable openings can be provided in the lid for filling the crucible with coating material. These closable openings are preferably arranged between the first and/or second IR radiation sources in such a way that it is possible to (re)fill the crucible with coating material without dismantling the IR radiation sources or removing the lid from the crucible.

Preferably, the first and second heating sources can be operated independently of each other. If the first and/or second heating source comprises several IR radiation sources, it may furthermore be advantageous if the individual IR radiation sources can also be operated independently of one another.

Preferably, the crucible forms a guide portion through which the vaporized coating material is guided to the at least one outlet opening. Preferably, the second heating source is adapted to heat also this guide portion. Since in conventional coating sources, coating material is often deposited also in the region of this guide portion, this arrangement can be used to either prevent such deposits or to clean the guide portion, for example after a coating process. Particularly preferably, the second heating source is adapted to specifically and selectively heat the at least one outlet opening and/or the guide portion. This can be achieved, for example, by the second heating source comprising one or more IR radiation sources that can be focused on different areas. Alternatively, the second heating source can also have several IR radiation sources that can be controlled separately from one another, so that by switching one or more IR radiation sources on and off, only the at least one outlet opening or only the guide portion or both the at least one outlet opening and the guide portion can be heated in a targeted manner.

Preferably, the guide portion comprises a layer of a poorly thermally conductive material, wherein preferably the thermal conductivity through the layer is at most 10 W/m·K, more preferably at most 5 W/m·K and particularly preferably at most 1 W/m·K. Such a layer of a poorly thermally conductive material can be advantageous, for example, if the guide portion is adjacent to a region of the crucible that is heated particularly strongly by the first heating source, for example the region of the crucible that receives the coating material. The layer of a poorly thermally conductive material can then contribute to the temperature of the coating material on the one hand and the guide portion on the other hand being better adjusted independently of each other. For similar reasons, it may be preferable for the guide portion to comprise a layer of an IR radiation reflecting material, wherein the layer preferably has a mean reflection of at least 30%, more preferably at least 50% and particularly preferably at least 70% over the wavelength range from 0.5 μm to 5.0 μm. This layer of an IR radiation material also is to improve control of the temperature equilibrium within the coating source, for example by ensuring that the second heating source primarily heats up the outlet opening and that its radiant energy does not lead to excessive heating of the guide portion.

It is also preferred that the inner cross-section of the guide portion is tapered in the direction of the at least one outlet opening. This can benefit the material flow of the vaporized coating material. In particular, however, such a taper ensures that a portion of the radiant energy emitted by the second heating source also impacts the surface of the guide portion. Using the angle of this taper, the proportion of radiant energy to be absorbed by the surface of the guide portion can also be adjusted. Preferably, a tangent to the taper includes an angle between 2° and 30° with the vertical, more preferably between 4° and 20° and particularly preferably between 6° and 10°.

Furthermore, a shield against IR radiation can be arranged in front of the at least one outlet opening (i.e. on the inside). This shield can also allow for an improved temperature equilibrium within the coating source. For the same reason, a shield against heat conduction and/or IR radiation can be arranged in the region around the at least one outlet opening. Furthermore, an additional device for heating and/or cooling can be arranged in the region around the at least one outlet opening. Since in some coating processes the substrate to be coated passes quite closely by the outlet opening of the coating source and the substrate is heated up considerably during the coating process, the substrate itself can serve as a heating source, which can make shielding against heat radiation and/or a device for cooling necessary.

Preferably, the crucible contains coating material to be vaporized, particularly preferably a material with a vaporization temperature of at most 1,000° C. and particularly preferably one or a combination of the following materials: Se, CdTe, CdSe, CdS, Pbl2, KCl, NaCl, RbF and/or CsCl.

The coating source according to the invention can be used in a wide variety of coating processes. It is therefore envisaged that the at least one outlet opening comprises one or a combination of the following outlet openings: a dot-shaped opening; a plurality of dot-shaped openings, which are preferably arranged along a straight line or a zigzag line, wherein the dot-shaped openings may be of the same size or of different size; a slit-shaped opening, preferably having the shape of a straight line or a zigzag line; a plurality of slit-shaped openings, wherein the slit-shaped openings may be of the same size or of different size and/or have the same shape or a different shape.

The present invention is further directed to a coating plant with a coating source as described above. The coating plant is particularly preferably adapted to coat substrates from above.

Furthermore, the present invention is directed to a method for coating substrates using a coating source as described above. In the method, a substrate to be coated is positioned under the coating source and the substrate is coated by means of the coating source. The substrate can rest with respect to the coating source during the coating process. Alternatively, the substrate can be moved with respect to the coating source or vice versa during coating.

The present invention provides several advantages. By designing the coating source with the additional direct heating option outside the crucible area, the heating of the crucible filling is separated from the heating of the outlet opening in terms of time and geometry. This allows the opening to be cleaned by heating before/after the process and can be quickly controlled via the condensation point during the process. The semi-transparent lid, which is also directly heated, remains clean due to the temperatures above the condensation point and acts as a hot mirror for the material vapor. To this end, uniform and particularly clean coatings can be achieved both statically and dynamically using PVD/CSS methods. In particular, contamination can also be prevented in coating processes in which the surface to be coated faces upwards. The present invention can in particular also be advantageously applied to the coating of large (at least 1 m²) glass substrates that are already coated or still uncoated, the coating of silicon wafers in a large-scale carrier or also the coating of other substrates in a medium format.

In the following, preferred embodiments of the present invention are described in more detail with reference to the figures. The Figures show:

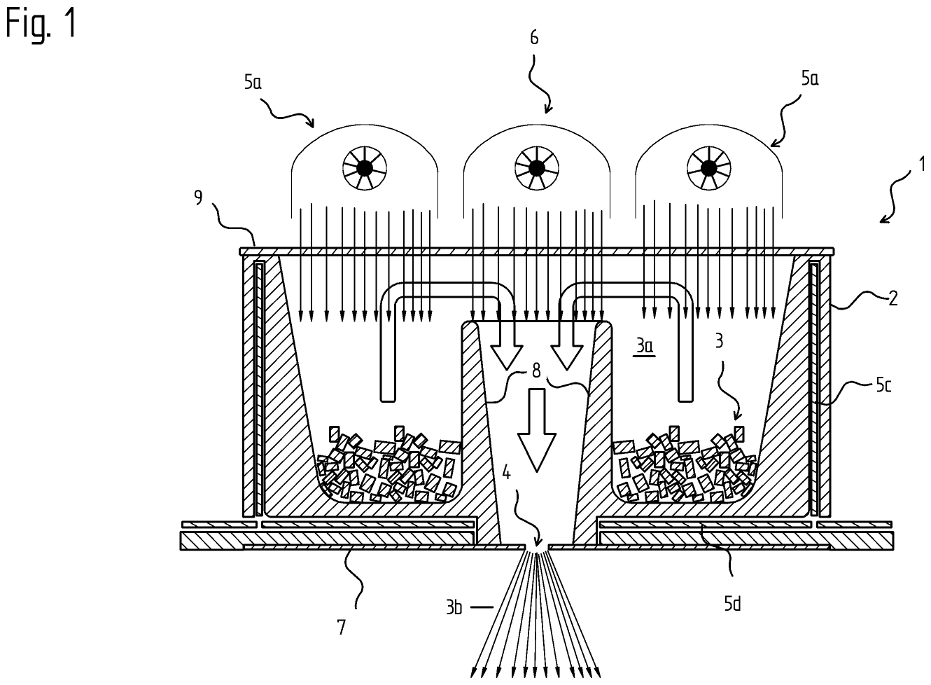

FIG. 1 a schematic longitudinal section of a coating source according to a preferred embodiment;

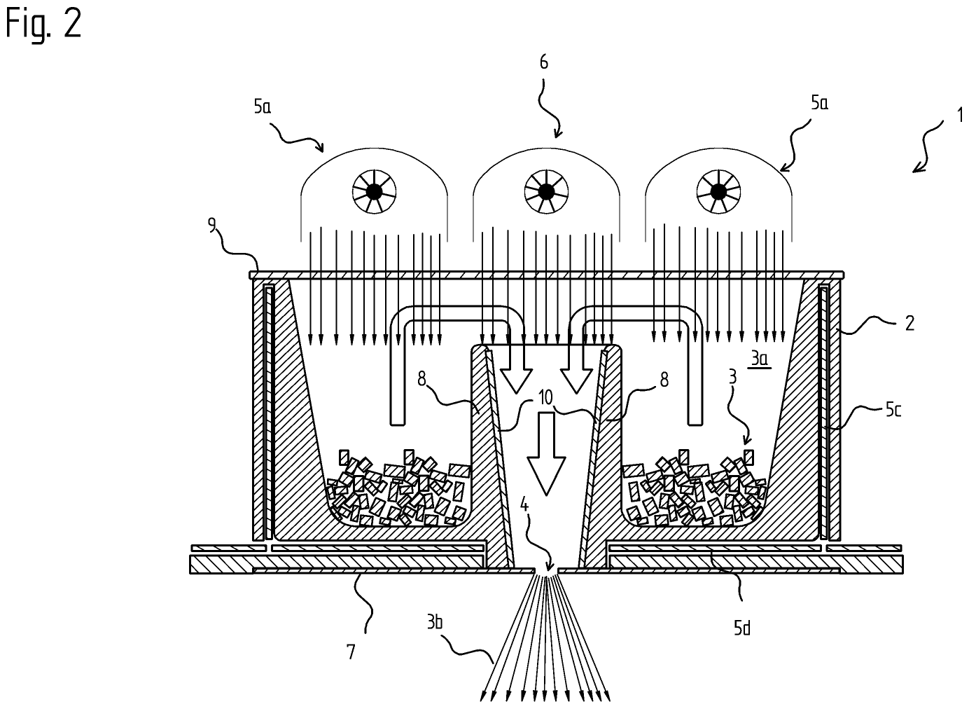

FIG. 2 a schematic longitudinal section of a coating source according to a further preferred embodiment;

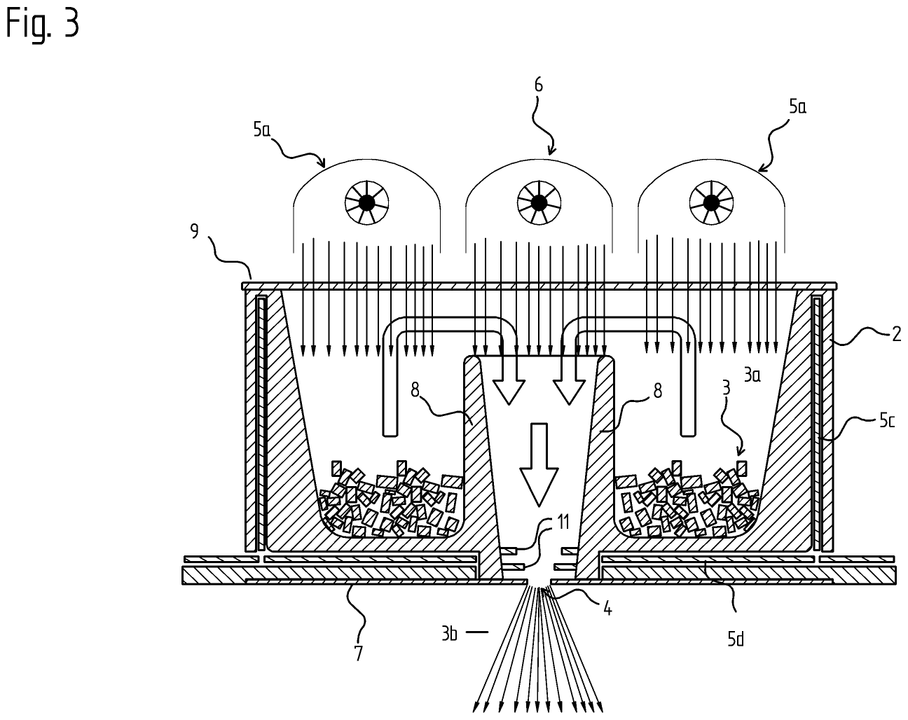

FIG. 3 a schematic longitudinal section of a coating source according to a further preferred embodiment;

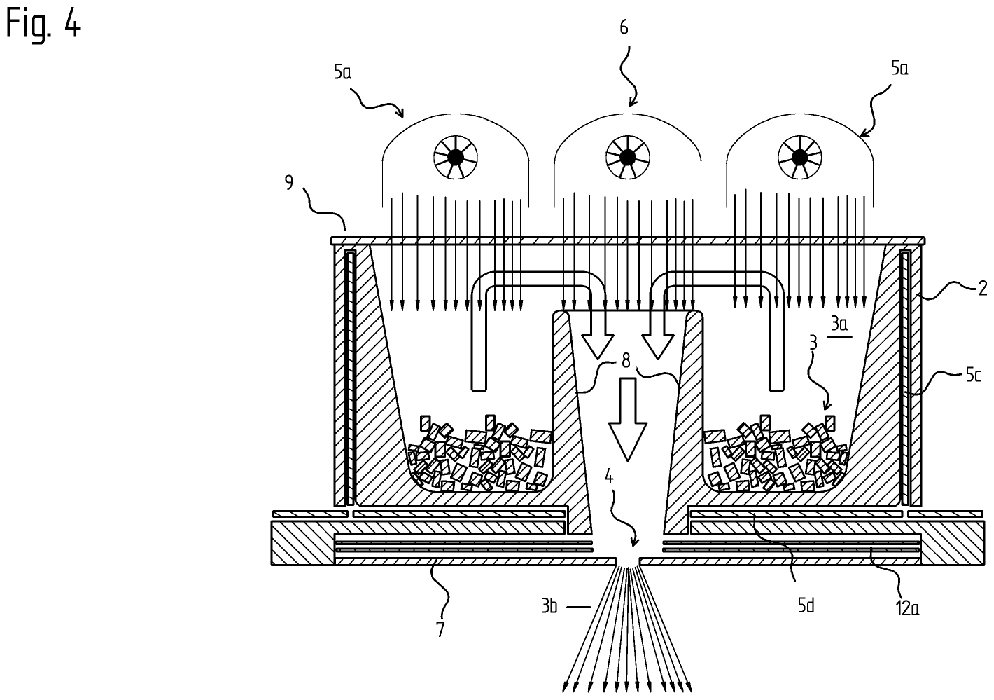

FIG. 4 a schematic longitudinal section of a coating source according to a further preferred embodiment;

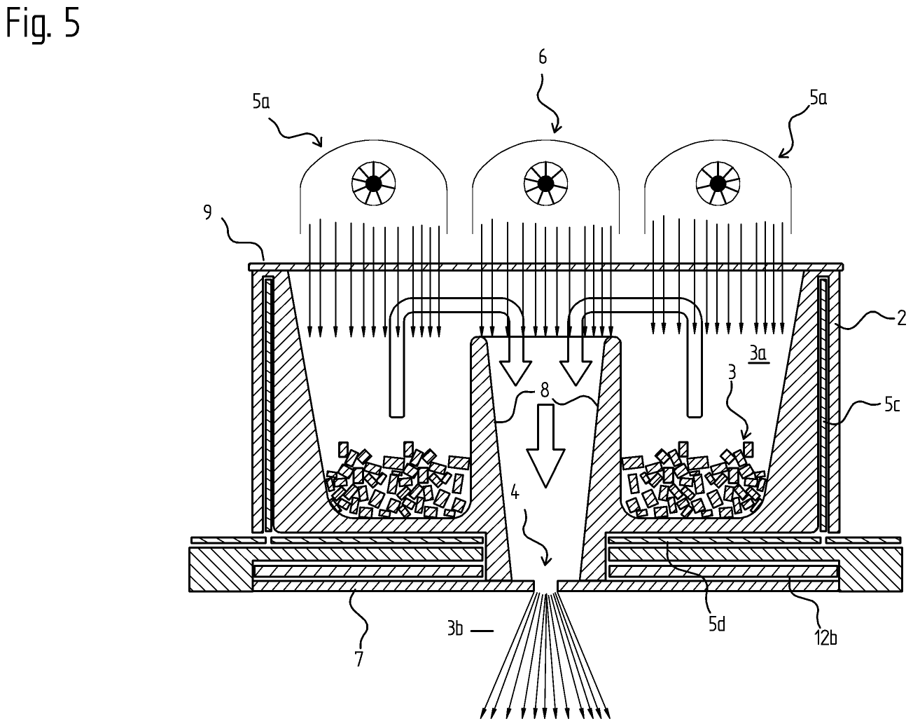

FIG. 5 a schematic longitudinal section of a coating source according to a further preferred embodiment;

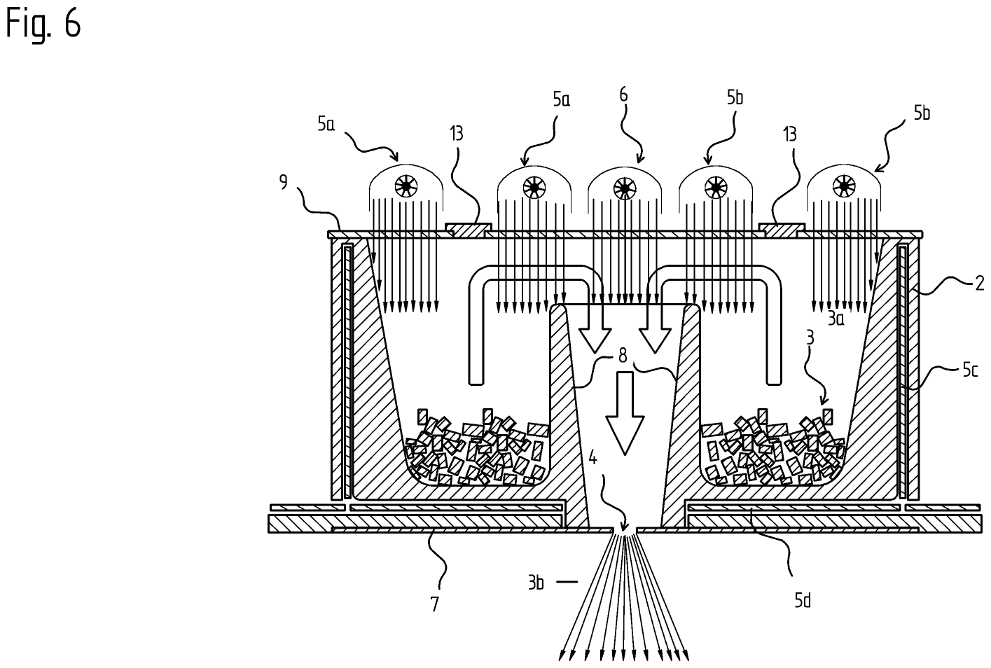

FIG. 6 a schematic longitudinal section of a coating source according to a further preferred embodiment;

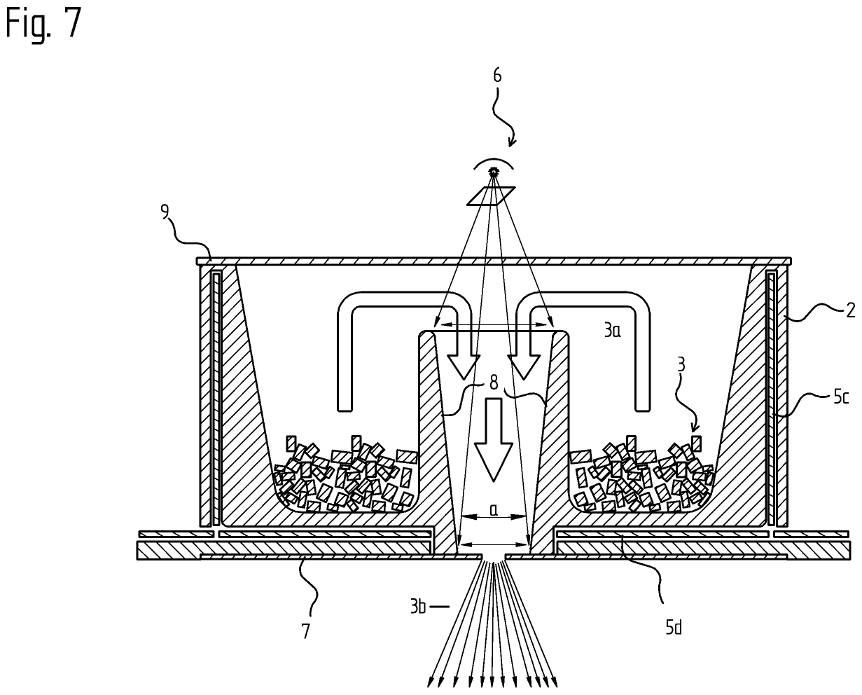

FIG. 7 a schematic longitudinal section of a coating source according to a further preferred embodiment;

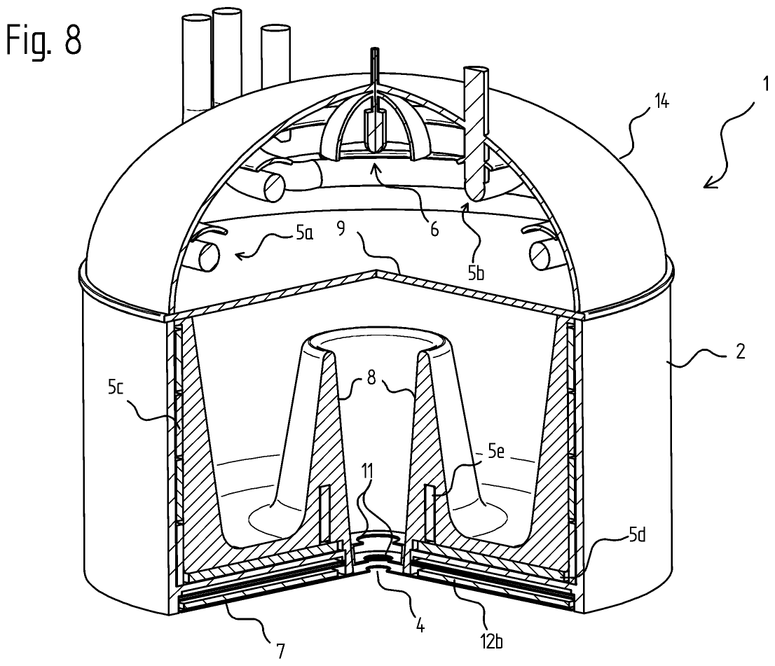

FIG. 8 a perspective partial sectional view of a coating source according to a further preferred embodiment;

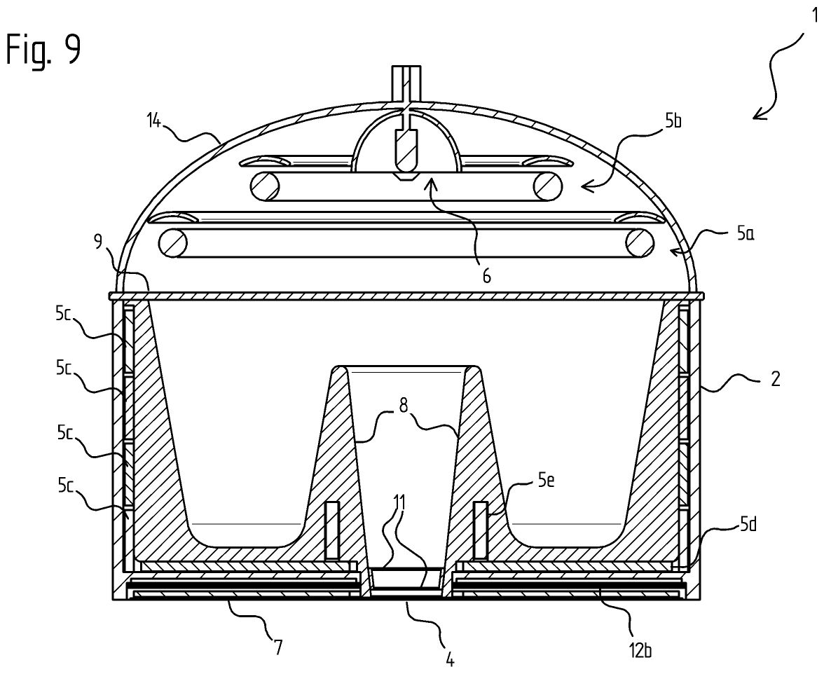

FIG. 9 a longitudinal section through the coating source according to FIG. 8;

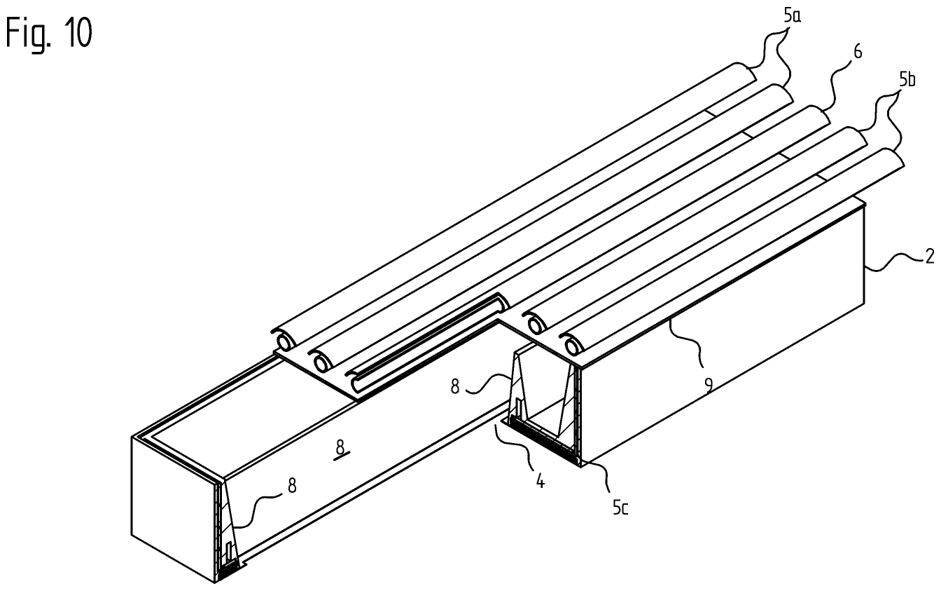

FIG. 10 perspective partial sectional view of a coating source according to a further preferred embodiment;

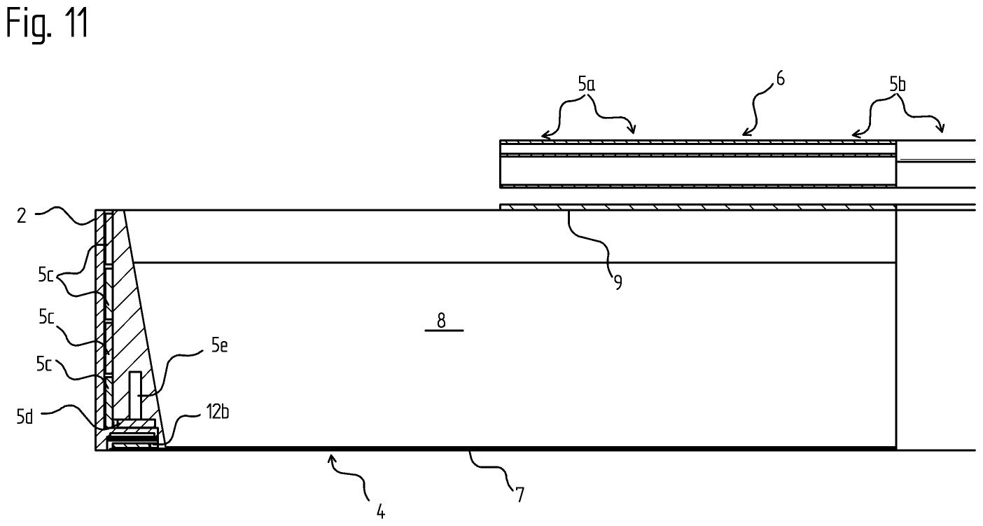

FIG. 11 a longitudinal section through the coating source according to FIG. 10;

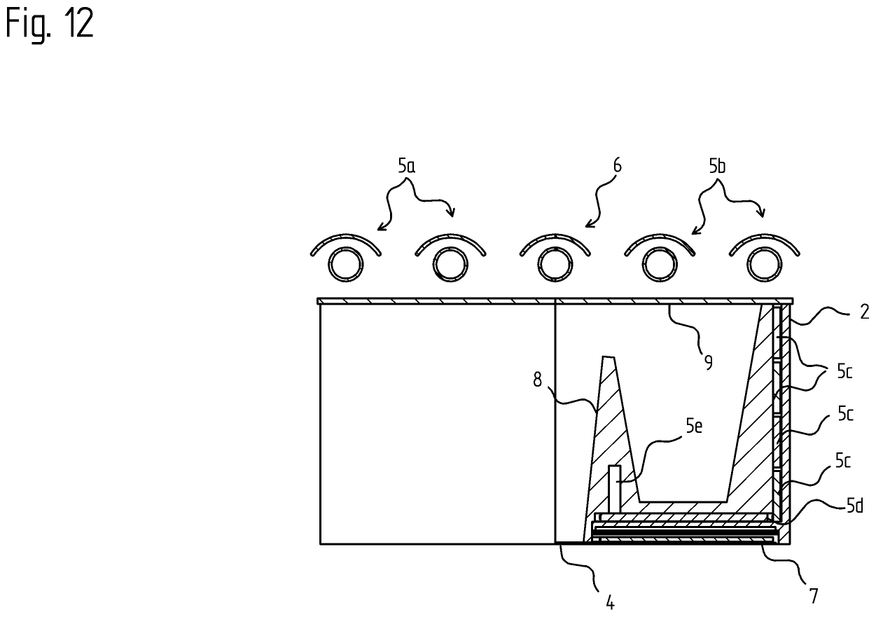

FIG. 12 a cross-section through the coating source according to FIG. 10;

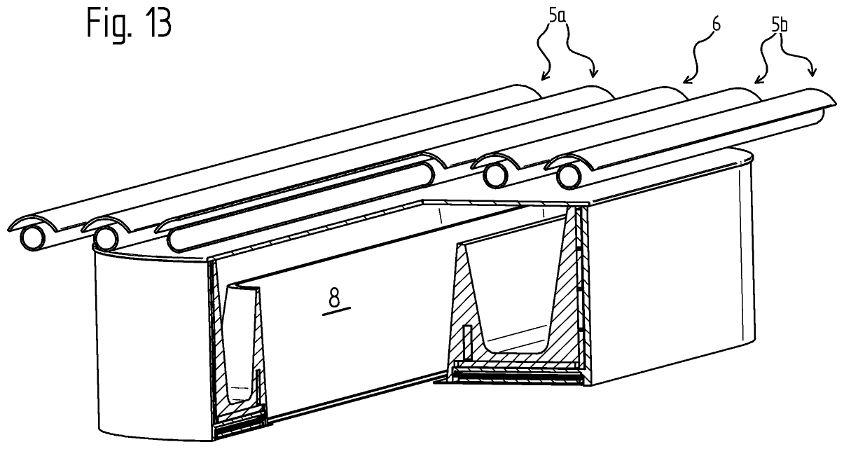

FIG. 13 a perspective partial sectional view of a coating source according to a further preferred embodiment;

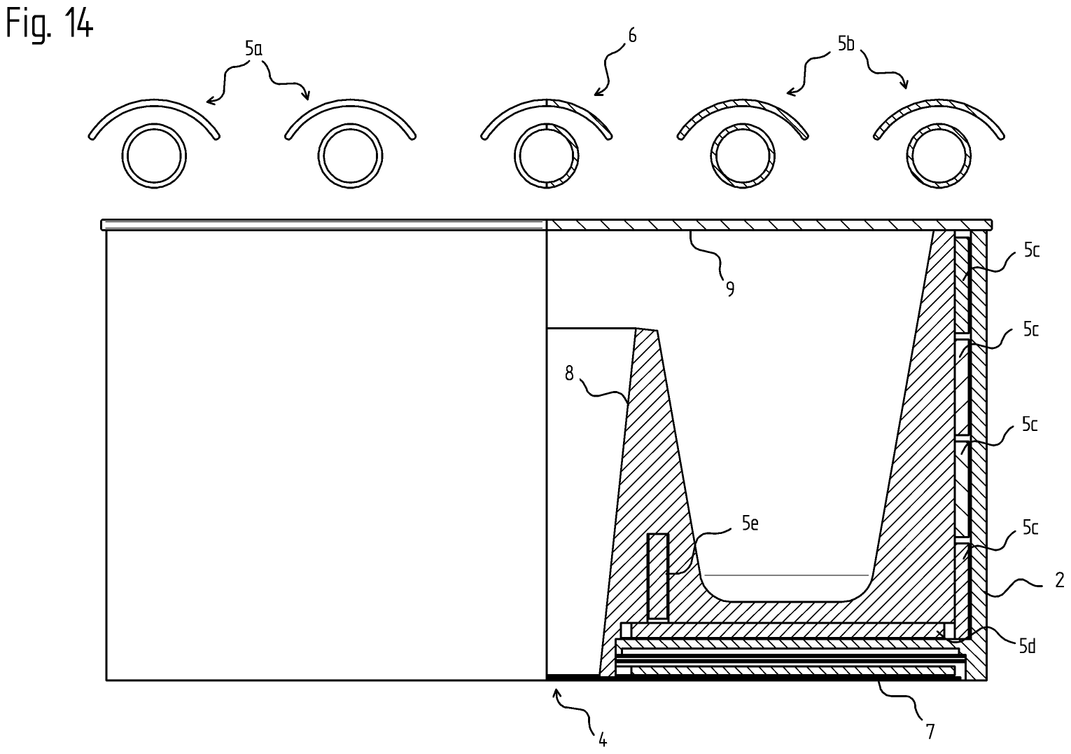

FIG. 14 a partial cross-sectional view of the coating source according to FIG. 13; and

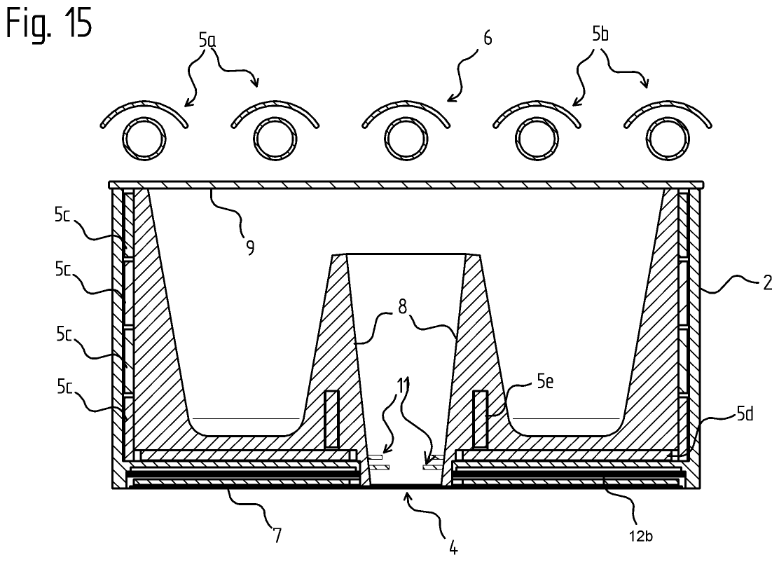

FIG. 15 a cross-sectional view of the coating source according to FIG. 13.

FIG. 1 schematically shows a longitudinal section through a coating source 1 according to a preferred embodiment of the present invention. The coating source 1 comprises a crucible 2 for vaporizing coating material 3 and at least one outlet opening 4 for vaporized coating material 3a, 3b, wherein the coating source 1 comprises a first heating source 5a, 5b, 5c, 5d for heating the crucible 2 and the coating material 3 and a second heating source 6 for heating the at least one outlet opening 4. In the preferred embodiment shown, the first heating source comprises several heating elements 5c and 5d integrated into the crucible walls and two first IR radiation sources 5a and 5b. Alternatively, however, only one or more heating elements 5c and/or 5d integrated into the crucible walls could be provided or only one or more first IR radiation sources 5a and/or 5b.

In the preferred embodiment shown, the second heating source 6 consists of a separate IR radiation source that can be operated independently of the two IR radiation sources 5a and 5b. This allows the temperature of the outlet opening to be adapted independently of the remaining crucible temperature and, in particular, of the temperature of the coating material 3. If the temperature of the outlet opening 4 is sufficiently high, the vaporized coating material 3a will move along the arrows in FIG. 1 and exit the crucible 2 through the outlet opening 4 without the coating material 3a condensing in the region of the outlet opening 4. The vaporized coating material 3a then emerges from the outlet opening 4 in the form of a coating cone 3b to coat a substrate below the coating source 1 that is not shown.

Heating by means of the radiation sources 5a, 5b and 6 is carried out through a semi-transparent lid 9, which is used to close the crucible 2. Due to the semi-transparency of the lid 9, sufficient radiant energy can pass through the lid 9 to both heat the coating material 3 sufficiently and to heat up the outlet opening 4 sufficiently. On the other hand, some of the radiant energy emitted by the IR radiation sources 5a, 5b and 6 is also absorbed by the lid 9, so that it heats up to such an extent that no vaporized coating material 3a condenses on said lid. Moreover, this arrangement ensures a self-cleaning effect: if coating material 3a is deposited on the inside of the lid 9, its transmission of IR radiation is automatically reduced, which causes the lid 9 to heat up further and the deposited material to vaporize again.

In the preferred embodiment shown, the crucible 2 forms a guide portion 8 through which the vaporized coating material 3a is guided to the at least one outlet opening 4. In order to prevent vaporized coating material 3a from being deposited on the surfaces of said guide portion 8, the second heating source 6 is preferably suited to also heat said guide portion 8. In the preferred embodiment according to FIG. 1, this is achieved by the fact that the inner cross-section of the guide portion is tapered towards the at least one outlet opening 4 and the radiation angle of the IR radiation source 6 is selected to be so large that part of the emitted IR radiation impinges on the surfaces of the guide portion 8.

In the preferred embodiment shown, the outlet opening 4 is not formed directly by the crucible wall of the crucible 2. Rather, a plate 7 is provided on the bottom side of the crucible 2, in which the outlet opening 4 is formed. While the crucible 2 is usually made of graphite, the plate 7 can comprise one or a combination of the following materials: CFC, graphite, ceramic, glass, metal.

FIGS. 2 to 7 show further preferred embodiments of the coating source according to the invention, each of which differs from the coating source according to FIG. 1 in only a few features. Therefore, identical features in FIGS. 2 and 7 are not marked again with the corresponding reference signs.

In the embodiment shown in FIG. 2, the guide portion 8 comprises a layer 10 of a poorly thermally conductive material. This layer 10 is to ensure that the crucible parts arranged behind this layer 10, which on the one hand form the guide portion 8 and on the other hand also form the wall region for the supply of the coating material 3, become hotter than the outlet opening 4.

In the embodiment according to FIG. 3, a shield 11 against IR radiation is arranged in front of the at least one outlet opening 4. In the embodiment shown, this shield 11 consists of two shielding plates, which are also to ensure that the outlet opening 4 is colder than the crucible parts above it.

In the embodiment according to FIG. 4, a shield 12a against heat conduction and/or IR radiation is arranged on the bottom side of the crucible 2 in the region around the at least one outlet opening 4. For example, this shield may be a shielding plate 12a, which is to ensure that the bottom side of the outlet opening 4 or the plate 7 forming it is colder than the upper side.

Alternatively or additionally, an additional device 12b for heating and/or cooling can be arranged in the region around the at least one outlet opening 4, as shown schematically in FIG. 5.

In the embodiment shown in FIG. 6, closable openings 13 are provided in the lid 9 of the crucible 2 for filling the crucible with coating material. Preferably, the first IR radiation sources 5a and 5b are arranged such that the closable openings 13 are accessible and can be opened without having to dismantle the IR radiation sources 5a and 5b. For this purpose, in the embodiment shown in FIG. 6, both first IR radiation sources 5a and 5b of FIG. 1 are each replaced by two first IR radiation sources 5a and 5b, so that between each of two adjacent first IR radiation sources 5a and 5b, respectively, access to the closable openings 13 is maintained and homogeneous radiation exposure can nonetheless be ensured.

Preferably, the second heating source 6 is adapted to specifically and selectively heat the at least one outlet opening 4 and/or the guide portion 8. For this purpose, for example, a lockable IR radiation source 6 with corresponding focus and dimming devices can be used, which allows to vary the radiation angle α in a targeted manner, as shown in FIG. 7. Alternatively, several independently controllable second IR radiation sources 6 could also be provided with which the outlet opening 4 and/or the guide portion 8 can be selectively heated.

As a matter of course, the various additional features, each of which is shown in isolation in FIGS. 2 to 7, can also be combined with one another in one and the same embodiment. Ultimately, all these features have the purpose to be able to control the temperature equilibrium within the coating source as specifically as possible. Thus, a combination of the various features interacts advantageously so as to allow an even more specific control.

FIGS. 8 and 9 show a preferred embodiment of a coating source according to the invention in a perspective partial sectional view and in a longitudinal sectional view, respectively. The embodiment of FIGS. 8 and 9 corresponds roughly to the arrangement according to FIG. 1. However, in the case of FIGS. 8 and 9, the concept of FIG. 1 is implemented for a point source, which results in a circularly symmetrical arrangement and implies that the two separate first IR radiation sources 5a and 5b according to FIG. 1 form a single, circularly arranged IR radiation source 5a in the embodiment according to FIGS. 8 and 9. However, in this embodiment, a further inwardly and upwardly shifted first IR radiation source 5b is additionally provided.

As a matter of course, in the present context, the term point source is not to be understood in a strictly mathematical sense since the outlet opening 4 is not dot-shaped but has the form of an extended circular disk.

As for the rest, the features discussed with reference to FIG. 1 essentially correspond to the corresponding features in FIGS. 8 and 9. In addition, two shielding plates 11 (analogous to FIG. 3) and an additional cover 14 are provided above the first and second heating sources. The additional heating or cooling element 12b (see FIG. 5) is also present in the embodiment according to FIGS. 8 and 9. Moreover, a heating element 5e of the first heating source extends partially into the guide portion 8.

In FIGS. 10 to 15, the concept according to FIG. 1 is implemented with different versions of linear sources. Accordingly, the first and second IR radiation sources 5a, 5b and 6 are elongated, linear IR emitters, in contrast to their circular arrangement in FIGS. 8 and 9. For example, two separate linear regions for receiving coating material can be formed by the likewise linear guide portion 8, as can be seen in FIGS. 10 to 12. Alternatively, these two regions, which are to receive the coating material, can be connected to each other at the longitudinal ends via a curve, as can be seen in FIGS. 13 to 15. The latter arrangement can be particularly advantageous to achieve a homogeneous temperature distribution and correspondingly good coating quality also in the marginal regions of the linear source.

The radiation sources 5a, 5b and 6 can also distribute the heating power adapted to the crucible geometry, e.g. as a linear IR double source: one heating coil as a continuous coil and the other heating coil consisting of two, three or more segments with different heating power. In this way, all four crucible walls can be heated evenly from above and separately from the outlet opening. Equally, all IR sources above the crucible lid can be segmented as required and thus be designed with a conveyed surface power distribution.

1. A coating source for a coating plant, wherein the coating source comprises a crucible for vaporizing coating material and at least one outlet opening for vaporized coating material, wherein the coating source comprises a first heating source for heating the crucible and/or the coating material and a second heating source for heating the at least one outlet opening, wherein the second heating source comprises one or more second IR radiation sources, wherein the crucible is closed with a lid, wherein the second IR radiation source is arranged outside said closed crucible and the lid is at least semi-transparent for the IR radiation of the second IR radiation sources, wherein the at least one outlet opening is arranged on a first, lower side of the crucible and the lid closes a second, opposite side of the crucible.

2. The coating source according to claim 1, wherein the first heating source comprises one or more heating elements integrated into the crucible walls and/or one or more first IR radiation sources.

3. (canceled)

4. The coating source according to claim 1, wherein the first IR radiation sources are arranged outside the closed crucible and the lid is at least semi-transparent for the IR radiation of the first IR radiation sources.

5. (canceled)

6. The coating source according to claim 1, wherein one or more closable openings are provided in the lid for filling the crucible with coating material.

7. The coating source according to claim 1, wherein the first and second heating sources can be operated independently of each other.

8. The coating source according to claim 1, wherein the crucible forms a guide portion through which the vaporized coating material is guided to the at least one outlet opening.

9. The coating source according to claim 8, wherein the second heating source is adapted to heat the guide portion.

10. The coating source according to claim 9, wherein the second heating source is adapted to specifically and selectively heat the at least one outlet opening and/or the guide portion.

11. The coating source according to claim 8, wherein the guide portion comprises a layer of a poorly thermally conductive material, wherein the thermal conductivity through the layer is at most 10 W/m·K.

12. The coating source according to claim 8, wherein the guide portion comprises a layer of an IR radiation reflecting material, wherein the layer preferably has a mean reflection of at least 30%, over the wavelength range of 0.5 μm to 5.0 μm.

13. The coating source according to claim 8, wherein the inner cross portion of the guide portion is tapered towards the at least one outlet opening.

14. The coating source according to claim 1, wherein a shield against IR radiation is arranged in front of the at least one outlet opening.

15. The coating source according to claim 1, wherein a shield against heat conduction and/or IR radiation is arranged in the region around the at least one outlet opening.

16. The coating source according to claim 1, wherein an additional device for heating and/or cooling is arranged in the region around the at least one outlet opening.

17. The coating source according to claim 1, wherein coating material to be vaporized with a vaporization temperature of at most 1,000° C. is arranged in the crucible.

18. The coating source according to claim 1, wherein the at least one outlet opening comprises one or a combination of the following outlet openings: a dot-shaped opening; a plurality of dot-shaped openings, wherein the dot-shaped openings are of the same size or of different sizes; a slit-shaped opening; a plurality of slit-shaped openings, wherein the slit-shaped openings are of the same size or of different sizes and/or have the same shape or different shapes.

19. A coating plant with a coating source according to claim 1.

20. The coating plant according to claim 19, wherein the coating plant is adapted to coat substrates from above.

21. A method for coating substrates using a coating source according to claim 1, wherein the method comprises:
positioning a substrate to be coated under the coating source according to claim 1 and coating the substrate using the coating source.

22. The method according to claim 21, wherein the substrate is at rest with respect to the coating source during coating.

23. The method according to claim 21, wherein the substrate is moved with respect to the coating source or vice versa during coating.

24. The coating source according to claim 1, wherein the lid has a mean transmission of at least 5% over the wavelength range from 0.5 μm to 5.0 μm.
